(19) United States
(12) Patent Application Publication
(10) Pub. No.: US 2023/0282526 A1
(43) Pub. Date: Sep. 7, 2023

(54) Method and device for measuring the thickness of thin films even on rough substrates

(71) Applicant: Fyzikální ústav AV CR, v. v. i., Czech Republic (CZ)

(72) Inventors: MARTIN LEDINSKY, Stresovice (CZ); ROMAN DVORAK, Stresovice (CZ); ANTONIN FEJFAR, Stresovice (CZ)

(21) Appl. No.: 18/009,598

(22) PCT Filed: Jun. 15, 2021
(86) PCT No.: PCT/CZ2021/050063

§ 371 Date: Dec. 9, 2022

(30) Foreign Application Priority Data
Jun. 15, 2020 (CZ) PV 2020-345

(51) Int. Cl. H01L 21/66; G01B 11/06; C23C 14/54

(52) U.S. Cl. CPC H01L 22/12; G01B 11/0658; G01B 11/0683; C23C 14/547; G01B 2210/56

(57) ABSTRACT

The present invention relates to a method and device for fast and accurate mapping of the thickness of a thin film (10), particularly on a silicon wafer. The method comprises of irradiating the thin film (10) with excitation radiation of at least two wavelengths, wherein a luminescent image is captured during irradiation. In a preferred embodiment, the silicon wafer can move, for example during transport on a belt in a production line. These procedures can be used for online diagnostics of silicon wafer thicknesses in the production of solar cells. Exemplary embodiments include a method and device for obtaining images of an entire silicon wafer and can provide quick feedback for process control if preferably connected to a computing unit.

### TECHNICAL FIELD

The present invention relates to a method and device for determining the thickness of thin films of material by absorbing excitation and/or luminescence radiation of the substrate, wherein in one embodiment the substrate may be a rough substrate.

In one embodiment, the method and device according to the invention relate to determining the thickness of a silicon thin film, in particular, amorphous or microcrystalline silicon, deposited on silicon wafers, i.e., structures used in photovoltaics.

In another embodiment, the present invention relates to monitoring the thicknesses of silicon thin films, in particular, amorphous or microcrystalline silicon, during the industrial production of solar panels.

### BACKGROUND ART

Solar panels use semi-conductor solar cells, which consist of many thin contact films, to convert light radiation into electricity. Some films may be prepared from a semi-conductor material, such as amorphous or microcrystalline silicon. These are most often used for the passivation of surface defect states in crystalline silicon and serve as selective contacts, enabling the collection of charge carriers and the generation of photogenerated voltage.

It is known that the thickness of thin silicon films is an essential parameter for the efficiency of these processes. It must be sufficient for the purpose of passivation or selective doping, but it must not limit the collected current (1). The optimal thickness in terms of photovoltaic conversion is about 10 nm. Because the films are deposited on a rough surface optimised for optical light collection, it is practically impossible to use standard methods for measuring thin films (ellipsometry, interference, etc.), as discussed, for example, in (2). Determining the thickness of the thin silicon film is therefore essential and desirable for a well-functioning application.

The need to display the thickness of thin silicon films over the entire active surface is becoming important for optimised solar cells with rear contacts. The front of these cells remains completely unobstructed, thus avoiding shielding. It leads to a maximum no-load current and voltage and a record efficiency for silicon cells of 26.7% (3). For the industrial production of this type of cell, it is necessary to replace the lithographic steps, for example, by means of deposition through a mask (4). Checking the shape of the thin silicon contacts created by shielded deposition is essential to ensure optimal cell operation.

Known thickness measurements are available from a non-patent document—article (2). The paper describes a non-destructive method providing the thickness of a passivation α-Si:H film deposited on a crystalline silicon wafer with an accuracy better than 0.5 nm. The wafers have a textured surface, which is formed by protrusions in the shape of pyramids with a height of several μm. Non-passivated (without a thin silicon film) silicon wafers show recombination surface defects, and therefore, it is necessary to cover them with a passivation layer, which is usually made of amorphous silicon doped with hydrogen (α-Si:H). Silicon wafers treated in this way enable the production of a high-voltage, no-load solar cell. It is also discussed in the article that the above-mentioned preferred properties can be optimised by controlling the passivation silicon film thickness. The published point measurement method of a thin film uses Raman spectroscopy. Raman backscattered photons, as well as excitation-laser photons, are absorbed in a thin film of silicon. The thickness of the passivation layer was then calculated on the basis of the measured intensities of the Raman signal at various points on the sample according to the formula:

$$t = ln ( \frac{I}{{I}_{0}} ) / 2 α \qquad ( Equation 1 )$$

where t is the thin film thickness, I is the intensity of the detected Raman radiation at the measurement point, I₀ is the Raman radiation intensity on the uncovered surface and α is the attenuation constant of the amorphous silicon.

The above method requires a source of laser radiation, and the method is time consuming due to the small beam diameter and the need for point-to-point mapping, which is a disadvantage associated with the commercial production of solar cells. To check them, fast methods are needed to get the result in several seconds. The Raman map requires more time because each point is measured for approximately 1 s, resulting in hours-long point mapping, which is uninteresting from an industrial viewpoint.

A fast response can be achieved by measuring photoluminescence instead of Raman scattering and its direct display using a CCD detector. This method has been tested in the EU Horizon 2020 project NextBase (5). Even here, however, it was a long-lasting measurement, taking several minutes, unusable in terms of production cycle. In addition, it was loaded with a number of artifacts, especially parasitic infrared radiation from excitation sources and inefficient detection of the resulting luminescence, most of the signal was absorbed by a filter. This made it impossible to detect the thickness of deposited structures quickly, accurately and efficiently.

A method of imaging and inspecting silicon wafer defects suitable for photovoltaic solar panels, which uses photoluminescence for imaging, is known from US 2012/0142125 A1. The method uses incident radiation with a wavelength greater than 808 nm as an excitation source of silicon wafer radiation. The respective radiation emitter has a filter for selecting radiation of specific wavelengths. The luminescence radiation detector is also preferably provided with a filter. However, the method and device detect only the surface of the silicon wafers and detect any damage to the wafer. However, neither this method nor its modifications can detect the thicknesses of passivation layers of amorphous silicon.

In view of the closest prior art i.e., (5), falling within the same field of the method and device for detecting thin films and the same purpose by determining the thickness of a thin film, the technical problem to be solved is to determine the thickness of the thin film on a rough substrate with a speed enabling industrial use, while the measured samples are not destroyed during the measurement, all by means of a non-contact method.

### NON-PATENT LITERATURE CITATION

1. Makoto Tanaka, Mikio Taguchi, Takao Matsuyama, Toru Sawada, Shinya Tsuda, Shoichi Nakano, Hiroshi Hanafusa and Yukinori Kuwano. Development of New α-Si/c-Si Heterojunction Solar Cells: ACJ-HIT (Artificially Constructed Junction-Heterojunction with Intrinsic Thin-Layer). Japanese Journal of Applied Physics. 1992, pages Part 1, Number 11.
2. Profilometry of thin films on rough substrates by Raman spectroscopy. M. Ledinský, B. Paviet-Salomon, A. Vetushka, J. Geissbühler, A. Tomasi, M. Despeisse, S. D. Wolf, C. Ballif and A. Fejfar. 6, 2016, Nature, Vol. 37859, pages 1-6.
3. Silicon heterojunction solar cell with interdigitated back contacts for a photoconversion efficiency over 26%. Yoshikawa, K., Kawasaki, H., Yoshida, W. et al. 2, 2017, Nat Energy, Vol. 17032.
4. Simple processing of back-contacted silicon heterojunction solar cells using selective-area crystalline growth. Tomasi, A., Paviet-Salomon, B., Jeangros, Q. et al. 2017, Nat Energy 2, Vol. 17062.
5. Characterised and numerical simulations (WP8). [Online] [Cited: 6 May 2020.] https://nextbase-project.eu/characterized-and-numerical-simulations-wp8/.

### SUMMARY OF THE INVENTION

The first embodiment of the present invention relates to a method of measuring the thickness of thin films on a substrate. The term ‘thin films’ in this field means a film with a thickness from units to hundred nanometres, and this term is generally clear to those skilled in the art. In one embodiment, the thickness of the thin film is from 1 nm to 1 μm. In a preferred embodiment, the film thickness is from 1 nm to 500 nm. In a preferred embodiment, particularly suitable for solar cells, the detection of the film thickness ranges from 1 nm to 100 nm, even more preferably from 1 nm to 10 nm.

The second embodiment of the present invention relates to a device suitable for carrying out the measurement method according to the invention.

In preferred embodiments of the method and device, the invention can be used as part of quality and quantity (thickness) control of silicon thin films deposited on a silicon wafer in the industrial production of solar cells.

In another embodiment, the method or device can be used to determine the thickness of a thin film of any material having at least partial absorbance of the excitation radiation source or luminescence radiation of a substrate, such as a film of carbides, nitrides or oxides. In another embodiment, a luminescent material (e.g., silicon, GaAs, GaN or CdTe wafer) can be used as a substrate, or a film with detectable luminescence can be applied to the substrate. Examples of such films are organic dyes or hybrid organic-inorganic perovskites.

The method in accordance with the first embodiment of the invention provides measurement the thickness of a thin film of material having at least a partial absorbance of excitation radiation or at least a partial absorbance of luminescence radiation of the substrate. The thin film is placed on a substrate exhibiting luminescence radiation. The method includes the following steps:
a) irradiating the thin film on the substrate by a first source of excitation radiation;
b) detecting and recording luminescence radiation emitted by the substrate in response to irradiation from the first source of excitation radiation; wherein steps (a) and (b) take place simultaneously or at least partially simultaneously.
   The method further comprises the following steps:
c) irradiating the thin film on the substrate by a second source of excitation radiation; and
d) detecting and recording luminescence radiation emitted by the substrate in response to irradiation from the second source of excitation radiation; wherein steps (c) and (d) again take place simultaneously or at least partially simultaneously.
   In the next step, the recorded luminescence radiation from step (b) and (d) is compared, the invention is characterized in that,
   the detection step is performed through an optical filter transmitting radiation of a wavelength greater than 870 nm; and
   the irradiation steps are performed through optical filters transmitting radiation of a wavelength of less than 750 nm; and wherein
   the noise reduction step is performed on source images, which in some embodiments may be provided by Gaussian smoothing algorithms; and
   the comparison includes a data processing step and a thickness calculation using an algorithm based on the Beer-Lambert law.

In one embodiment, the noise reduction step can be applied to the determined map using FFT (Fourier Transform) of noise reduction algorithms.

The method according to the present invention provides the possibility of detecting the thickness of the thin film, preferably in several tens of nanometres. Another technical advantage is the possibility of detecting the thickness of a thin film deposited on a structured surface, i.e., also on rough substrates, while the detection takes place in several-second units. This effect is achieved by detecting luminescence from the excitation response of the substrate through the filters by at least two excitation sources, the purpose of detecting luminescence from the material response to the first excitation source being the measurement of the luminescence image of the substrate. The purpose of detecting luminescence from the response to the second source is to determine the changes in the luminescence image caused by the absorption on the thin film and the subsequent calculation of the thin film thickness map based on the Beer-Lambert law. Calibration with the help of the first excitation source is preferably used to detect the thickness of a thin film on a textured surface, such as a pyramid texture, a square texture, or other textures even randomly etched (the so-called black silicon). In addition, the determination of the film thickness is independent of the thin film production method and is not affected by the roughness or the substrate's other parameters, particularly the silicon wafer.

In this text, the use of the term simultaneously, or at least partially simultaneously, means a time overlap of two steps. The term simultaneously means the time period of two steps that start and end at the same time. The term at least partially simultaneously means a sequence of two steps that do not start simultaneously, but the second step starts before the end of the first step and may continue after the end of the first step or may end with the first step. In application to the present invention, in a certain embodiment, the luminescence represents fluorescence which, even after the excitation radiation has ended, has detectable afterglow even after a certain time period.

In the preferred embodiment of the method, a thin film of hydrogen-doped amorphous silicon material placed on a crystalline silicon wafer is detected. This preferred embodiment can be used in photovoltaics, in particular in the production of thin passivation layers of amorphous or microcrystalline silicon for heterojunction solar cells. In another preferred embodiment, the above method can be applied to polycrystalline silicon, even more preferably hydrogen-doped polycrystalline silicon, tandem or multi-junction cells with rear contacts.

In another preferred embodiment, the irradiation step is performed using an LED source. The advantage of using LEDs is the possibility of emitting almost monochromatic radiation. Another advantage of using LEDs can be seen in the effective removal of unwanted scattered radiation from the thin film by means of a pre-selected filter. LEDs are also advantageous due to the speed of measurement during the production or inspection process in production halls.

More preferably, the irradiation step is performed using a blue and a red LED to detect the thickness of the thin silicon film. An alternative to blue and red LEDs is the detection of silicon thin films using a monochromatic radiation source with medium wavelengths about 465 nm or about 625 nm. In another embodiment, it is possible to use polychromatic radiation sources provided with filters transmitting radiation of the above-mentioned wavelengths. The term about means the mean value and the values within the measurement uncertainty, usually up to 10%. In certain embodiments, which are particularly preferred for detecting silicon thin films up to 10 nm, the first source of excitation radiation of wavelength from 350 to 450 nm and the second source of excitation radiation from 600 to 750 nm may be used.

In another preferred embodiment, the detection method is performed through a suitable combination of excitation and/or detected radiation filters so as to remove the parasitic signal. Examples of such combinations are a solar-control glass for an excitation light source (absorbing parasitic thermal infrared radiation) and a GaAs polished wafer that absorbs scattered and reflected light from excitation sources. If a polychromatic source of excitation radiation is used, it is possible to choose a band-pass filter that effectively removes a wider range of scattered wavelengths. It is also possible to use a set of filters in the case of polychromatic radiation.

Detection is performed through a filter transmitting electromagnetic radiation with a wavelength above 870 nm (e.g., using a semi-conductor with a suitable band gap such as GaAs, or using interference filters), preferably in front of an optical sensor with NIR sensitivity, e.g., silicon CCD camera with sensitivity up to 1050 nm.

Irradiation with the first and second sources of excitation radiation is performed through a filter transmitting electromagnetic radiation below 750 nm, e.g., a solar-control glass or an interference filter.

In another preferred embodiment, the control unit displays the calculated thickness and communicates with the deposition film system. In a certain embodiment, based on the displayed thickness of the thin film, the deposition conditions can be adjusted so that the resulting thickness corresponds to the set requirements.

In another preferred embodiment, the excitation radiation intensity can be changed dynamically during irradiation. Thanks to the dynamic intensity of excitation radiation, it is possible to change the density of the excited carriers and thus also the amount of excited charge carriers. This is especially important for photovoltaic materials, it allows the determination of the pseudo volt-ampere characteristic, and thus the basic parameters of the resulting solar cell, no-load voltage or short-circuit current.

The second embodiment of the present invention relates to a device that can be preferably, but not exclusively, used to measure the thickness of a thin film of material. The material at least partially absorbs radiation from the source, or at least partially absorbs the luminescence radiation of the substrate. The device according to the invention comprises:
a source of monochromatic excitation radiation capable of emitting electromagnetic radiation of at least two different wavelengths in succession;
at least one detector configured to detect luminescence radiation from the substrate, the detector being configured to detect simultaneously, or at least partially simultaneously, with the emission of excitation radiation.
The essence of the device according to the invention lies in the fact that
the detector is fitted with a filter transmitting electromagnetic radiation at wavelengths exceeding 870 nm; and
the excitation radiation sources are provided with filters transmitting radiation at wavelengths of less than 750 nm; and the device further comprises
a computing unit storing data on the intensities of electromagnetic radiation from the thin film material and processing the data so as to be adapted to determine the thickness of the thin film based on the Beer-Lambert law.

The device according to the present invention is capable of surface displaying of the thin film thickness, in particular thin silicon films deposited on a silicon wafer. The described device can determine the film thickness in several units up to hundreds of nanometres and, in addition, with detection on the textured substrate surface. In a preferred embodiment, a near-infrared (NIR) optical focal plane array can be used for detection. The device according to the invention provides a high measuring speed and a sufficiently accurate measurement of film thickness.

In the preferred embodiment, the excitation radiation source is at least two LEDs emitting radiation with a mean wavelength of about 465 nm, preferably a blue LED; and the second source of excitation radiation emits radiation with a mean wavelength of about 625 nm, preferably a red LED.

In another preferred embodiment, the device comprises an excitation radiation intensity modulator.

In another preferred embodiment, the device comprises a control unit communicating with the deposition system applying the individual films so that the control unit is able to affect the deposition conditions according to the desired thin film thickness.

In another preferred embodiment, the device or any of the above preferred embodiments is used to detect the thicknesses of silicon thin films on a silicon wafer for use in solar panels.

In another preferred embodiment of the detection of the thicknesses of the thin films of solar cells, it is possible to place a silicon wafer on a sliding band on which the wafers with deposited thin films move.

### BRIEF DESCRIPTION OF DRAWINGS

FIG. 1 illustrates an algorithm of the method for determining the thickness of thin films according to the present invention and its preferred embodiments.

FIG. 2 is a schematic diagram of the device according to the present invention.

FIG. 3 is a schematic diagram of the device according to the present invention in preferred embodiments.

FIG. 4 is a schematic diagram of the device according to the present invention in a preferred embodiment focused on an assembly of excitation radiation source, detector and a set of filters.

FIG. 5 is a detailed drawing of a portion of the assembly according to FIG. 4.

FIG. 6 shows a measurement record of a photoluminescence image of amorphous silicon bands excited by blue excitation.

FIG. 7 shows a measurement record of a photoluminescence image of amorphous silicon bands excited by red excitation.

FIG. 8 shows the resulting representation of amorphous silicon bands using the present invention.

FIG. 9 is a direct comparison of the results obtained by the present invention (luminescence) method with the results obtained by Raman spectroscopy.

### DETAILED DESCRIPTION OF THE EMBODIMENTS

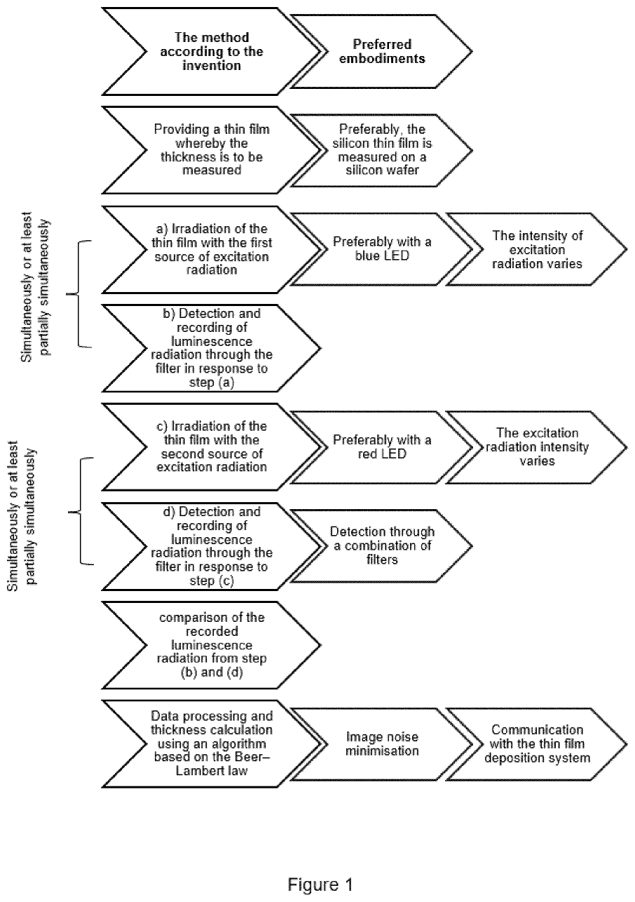

FIG. 1 shows the steps of the method for determining the thickness of thin film 10. The thin film 10 must be of a material capable of at least partially absorbing the excitation radiation or at least partially absorbing the luminescence radiation of the substrate 11. Examples of such materials are thin-film silicon, carbon films, GaAs films or hybrid organic-inorganic perovskites.

The thin film 10 is placed on the substrate 11. Example of combinations of the thin film 10, substrate 11 and excitation sources 21 and 22 is a silicon wafer, a thin film of amorphous silicon and an LED, with the emission of about 625 nm and with the emission of about 465 nm.

In the first step of the method according to the invention, the thin film 10 on the substrate 11 is irradiated by the first source 21 of excitation radiation. In the case of a silicon wafer with an amorphous silicon thin film, the first source 21 is suitably selected as a red LED with the emission of about 625 nm. The substrate 11 absorbs excitation radiation and in response emits luminescence radiation which passes through the thin film 10. Luminescence radiation passing through the thin film 10 is detected simultaneously or at least partially simultaneously. The detected luminescence radiation intensity is stored in the computing unit 41. In the next step, the same thin film 10 is irradiated by the second excitation radiation source 22 and again simultaneously, or at least partially simultaneously, the luminescence radiation of the substrate 11 passing through the thin film 10 is detected, the intensity data being stored in the computing unit 41. The radiation detection always passes through the optical filter 3, which is suitably selected with respect to the excitation radiation or the luminescence radiation passing through the thin film 10. Examples of suitable optical filters 3 are e.g., GaAs wafer, layer of hybrid organic-inorganic perovskites, interference filters with suitable edge. The excitation sources 21 and 22 are also provided with filters 321 and 322 so as to transmit radiation with a wavelength of less than 750 nm. The optical filter 3 transmits radiation with a wavelength greater than 870 nm.

In the preferred embodiment of the method according to the invention, in particular, the silicon thin film 10 is measured on the silicon wafer 11.

In another preferred embodiment, the first source 21 of excitation radiation is a blue LED. In another embodiment, e.g., an Xe lamp is used as the radiation excitation source 21. Irradiation is performed through the filter 321, more preferably through a set of filters. Examples of individual filters are edge interference filters transmitting a suitable region of the spectrum or colour filters.

In another preferred embodiment, the excitation radiation intensity can be varied, thereby changing the density of the excited charge carriers in the substrate 11. Based on the modulation of the intensities of sources 21 and 22, it is possible to determine the quantum efficiency of the thin film and thus to predict the solar cell efficiency.

In the next step of the method according to the invention, the recorded luminescence radiation intensities are compared. The thickness calculation is based on a computer programme using an algorithm based on the Beer-Lambert law. Specifically, the intensities stored in the computing unit 41 are compared at each location of the thin film 10 or they are substituted in a formula according to the Beer-Lambert law (Equation 1) and the thickness of the thin film 10 is calculated.

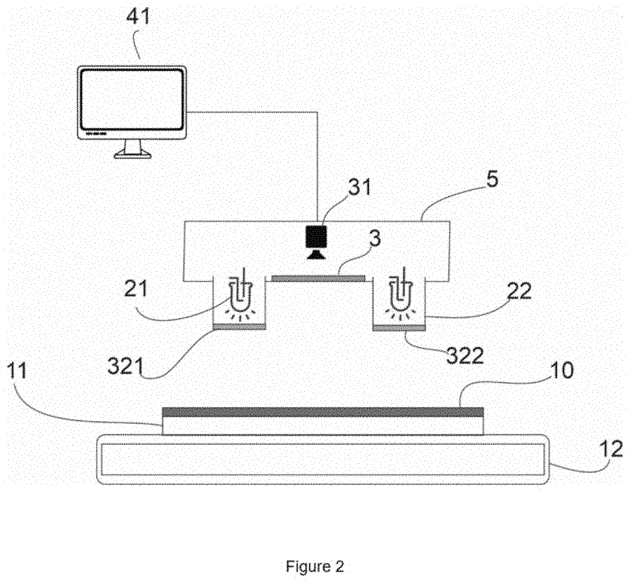

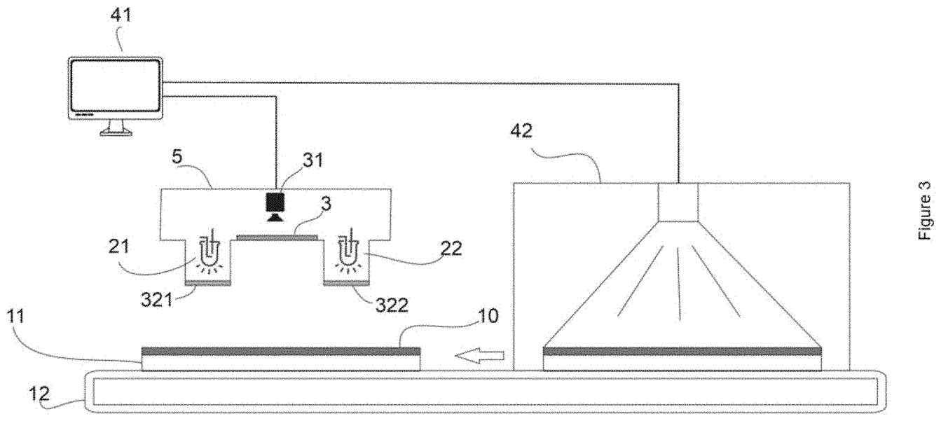

To carry out the method according to the present invention, the device shown in FIGS. 2 and 3 is preferably used. FIG. 2 shows the substrate 11 on which the thin film 10 is applied. The thin film 10 was deposited in the deposition system 42 shown in FIG. 3. The thickness of the thin film 10 is determined using the method and device of the present invention.

Preferably, the substrate 11 is placed on the band 12 which moves with the substrate 11. The device according to the invention further comprises the detection and excitation system 5, comprising at least two excitation radiation sources 21 and 22 emitting radiation of different wavelengths, preferably blue and red LEDs for detecting the thicknesses of the thin films 10 on the silicon wafer. The system 5 further comprises the detector 31, which is located above the filter 3, which transmits luminescence radiation passing through the thin film 10 of the substrate 11. The system 5 is further connected to the computing unit 41 which monitors and stores the intensities detected by the detector 31 and processes the thin film 10 thickness information. The computing unit 41 can also display the film thickness values in real time, which has the advantage of immediately evaluating the quality of the thin film 10 in real operation.

In the preferred embodiment of the device according to the present invention, the computing unit 41 is further connected to the deposition system 42 and is able to control the deposition conditions of depositing the thin film 10 on the substrate 11 according to the thin film 10 thickness information from the previous measurement. The band 12 is preferably connected to the deposition system 42 so that the substrate 11 with the thin film 10 is measured immediately after the deposition of the thin film 10.

The excitation radiation sources 21 and 22 are located above the filters 321 and 322, which filter the excitation radiation, the filter transmitting radiation with a wavelength of less than 750 nm. Filters 321 and 322 therefore transmit radiation which is able to excite the charges in the substrate 11. On the other hand, the excitation radiation sources 21 and 22 can also emit radiation of wavelengths in the infrared spectrum, which is the case of e.g., LED sources. Filters 321 and 322 effectively remove components of unwanted infrared radiation originating from sources 21 and 22 and the filter 3 transmits only infrared radiation originating from the substrate 11.

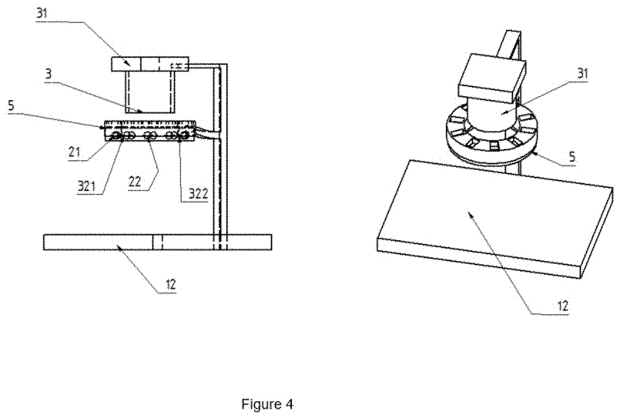

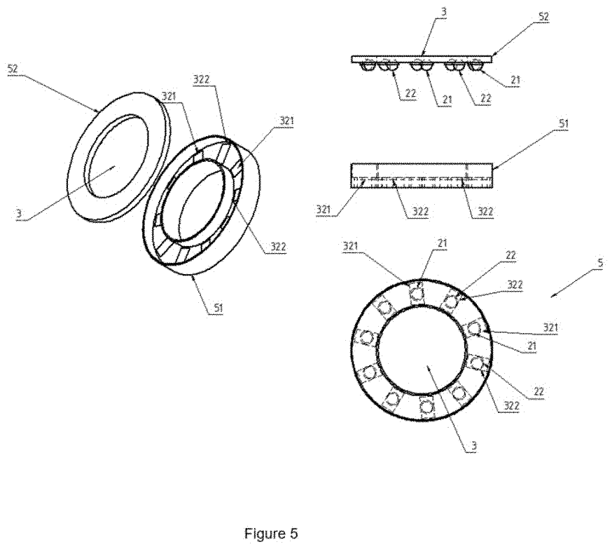

FIGS. 4 and 5 show the preferred embodiment of the system 5 above the band 12 and below the detector 31. In one embodiment, the filter 3 may be part of the system 5, as described in the following paragraph. The system 5 is oval in shape and consists of the bottom part 51 and the upper part 52. The bottom part 51 comprises filters 321 and 322 in the annulus, which transmit excitation radiation. The filters 321 and 322, together with the sources 21 and 22, are suitably alternately positioned so that the excitation radiation covers the entire area of the thin film 10. The top part 52 includes the excitation and radiation sources 21 and 22, which are located above the respective filters 321 and 322. In the middle of the system 5 there is an empty space for the passage of luminescence radiation coming from the thin film 10, whereby preferably the top part 52 can be provided with the filter 3. Such an embodiment can be preferred in particular with regard to the simple replacement of the detector 31.

The preferred embodiment of FIGS. 4 and 5 further allows homogeneous illumination of the thin film by excitation radiation, using a number of sources 21 and 22. Four sources 21 and four sources 22 were used in a particular arrangement according to this exemplary embodiment. Each source 21 and 22 was provided with filter 321 or 322, which was placed in the empty space at the bottom part 51 of the system 5.

The measured image is first denoised using the Gaussian smoothing. The smoothing parameters depend on the optical system of the embodiment. After creating the thickness map, it is possible to perform noise reduction of the measured data using methods based on the Fourier transform.

For samples with a low level of excited radiation, the measurement sensitivity and accuracy can be increased by detecting multiple images of a single sample irradiated with a single monochrome light. These images are then averaged or combined using a suitable algorithm. For example, using kappa-sigma clipping. Furthermore, the images are treated as images obtained from the sensor.

### Experimental Results

Article (2) discloses the method for measuring the thickness of thin film profiles using Raman spectroscopy. This method is practically unusable industrially due to its time-consuming nature, but it is precisely calibrated and was therefore used to verify the method accuracy according to the present invention.

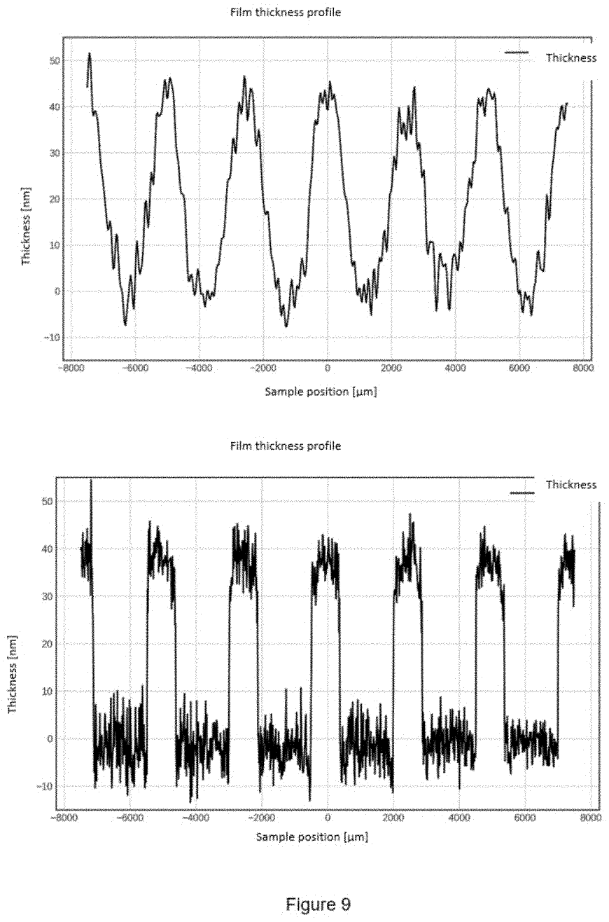

In carrying out the invention, the inventors performed the experiment described below. FIG. 9 shows a comparison of the thickness determined by the method of the present invention and by Raman spectroscopy.

In implementing the measuring device, the method of measuring the thickness of the thin film 10 was performed on a sample of an amorphous silicon film (aSi:H) deposited on the substrate 11 consisting of a crystalline silicon wafer.

The amorphous silicon thin film 10 was irradiated with blue light as one possible embodiment of the method. The LEDs were placed in a circular location with a hole in the middle to accommodate the detector 31 provided with the filter 3. The experiment avoided the emission of LEDs in the infrared region of light, which can also occur with these sources 21 and 22. This was achieved by using solar-control glass with light transmittance at wavelengths only up to 750 nm. The detector 31 with lens was placed above the hole in the excitation ring and provided with the filter 3. A silicon CCD camera with optimised sensitivity in the NIR part of the spectrum was used as the detector 31. Filter 3 used was a double-sided polished GaAs wafer.

The diodes emitted excitation radiation over the entire area of the sample with the measured thin film 10. Appropriate placement of light sources 21 and 22 and diffusers ensured uniform illumination of the sample. The red diode emitted light with a mean wavelength of 625 nm, while the blue diode emitted light with a mean wavelength of 465 nm. The choice of these wavelengths is particularly suitable for absorption by the film 10 made of amorphous silicon.

LEDs were preferably used due to the speed of measurement in the production or inspection process in production halls. Unlike laser spectroscopy, the entire wafer is irradiated and identified at one time. In addition, it is not necessary to aim the laser beam at a given wafer, therefore saving time. The silicon wafer as a whole, or as part of a larger whole, can move along the production line as part of the production process and stop moving at some point, triggering the said measurement method over a given part of the sample.

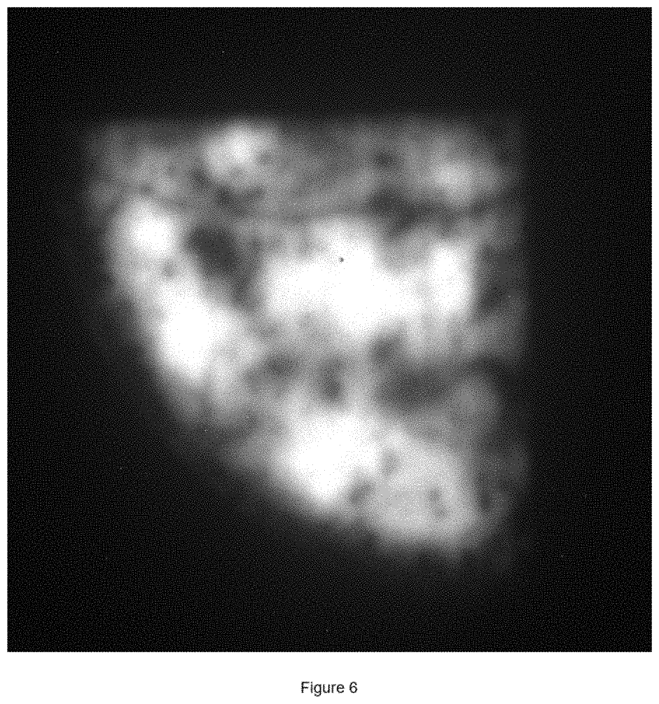

During irradiation of the sample with blue light, photoluminescence caused by excitation by blue light was measured using the optical focal plane array 3 (FIG. 6).

In the experimental setup, detector 31 was equipped with filter 3 transmitting emitted infrared light (wavelength of radiation is above 870 nm).

The photoluminescence information was stored in the computing unit 41 connected to the detector 31. Photoluminescence was measured with the optical detector 31 sensitive in the near infrared region. At the same time, it was necessary to filter out parasitic light from the visible area of the radiation using the edge filter 3 with a transmittance above 870 nm.

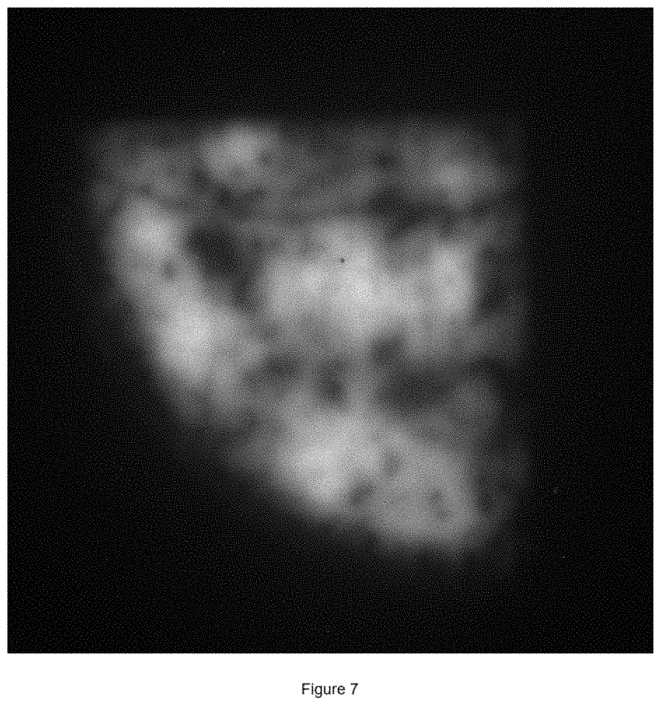

The wafer was subsequently irradiated with red light and photoluminescence was detected by the same detector 31 as a function of the excitation radiation of the red light (FIG. 7). The information on the photoluminescent response to red radiation was again stored in the computing unit 41.

Focal plane array capable of detecting photoluminescence (PL) radiation was used for each image. It is possible to use detectors, such as CCD, CMOS, etc. The PL detector 31 can preferably be positioned perpendicular to the wafer. The geometry can be defined by different detector slots or by the defining silicon wafer region from the detector's point of view. Therefore, excitation conditions are created on the moving wafer and photoluminescence radiation emanating from the wafer is detected at steady state.

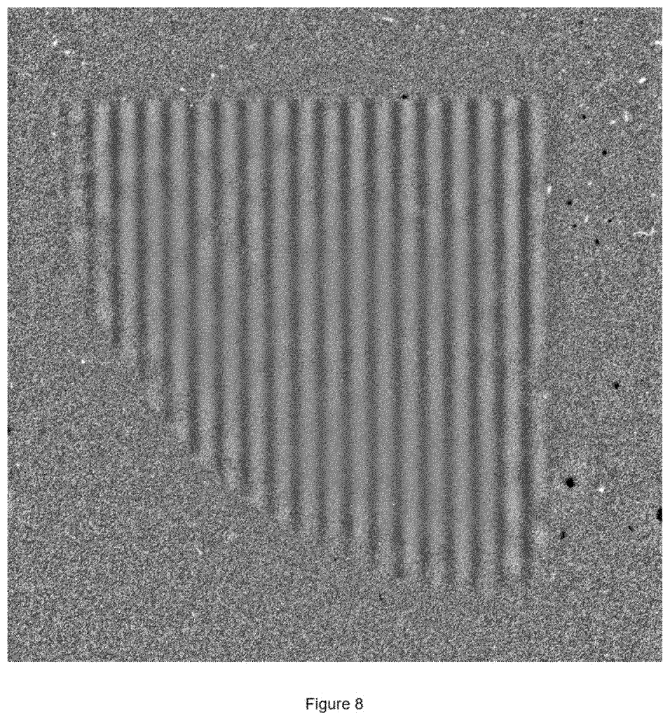

FIG. 8 shows the resulting representation of amorphous silicon bands, the record corresponding to the actual thickness of the thin film 10 deposited on the pyramid texture of the surface of the silicon wafer—the substrate 11.

FIG. 9 shows a comparison of the two methods. The thickness of the thin film 10 was determined independently in two ways. The first was an accurate but slow process of Raman spectroscopy—the bottom diagram in FIG. 9. In the second case, the thickness of the thin film 10 was determined on the basis of the method according to the present invention—the top diagram in FIG. 9. The change in the thicknesses of the thin film 10 depending on the position, i.e., the presence of bands formed during deposition through the shielding mask, can be clearly seen from the record. The record shows the thickness of the thin film 10, which reaches a height of approximately 45 nm. The record also shows that the method according to the present invention can also be used for the detection of thickness up to 10 nm, since the detected noise, and therefore the measurement error caused, reaches several units of nm at most.

In certain embodiments, the noise can be further removed or computerised by means of suitable computer programmes which advantageously make it possible to determine the thickness of the thin film 10 in several units of nm.

### INDUSTRIAL APPLICABILITY

The present invention presents the method and device for measuring the thickness of thin films. In one embodiment, the invention can be used during a manufacturing process to monitor the film thickness online and the measurement is further used as a guide to control the quality of the manufacturing process.

In the preferred embodiment, the efficiency of the conversion of light into electrical energy can be optimised by adjusting the thickness of the thin silicon films deposited on the silicon wafer of future solar cells.

1-13. (canceled)

14. A method of measuring the thickness of a thin film of material exhibiting at least partial excitation radiation absorbance or at least partial luminescence radiation absorbance, wherein the thin film is located on a substrate having luminescent properties, the method comprising:
a) irradiating the thin film on the substrate by a first source of excitation radiation;
and simultaneously, or at least partially simultaneously;
b) detecting and recording of luminescence radiation emitted by the substrate in response to irradiation from the first source of excitation radiation;
c) irradiating of the thin film on the substrate by a second source of excitation radiation; and simultaneously, or at least partially simultaneously;
d) detecting and recording of luminescence radiation emitted by the substrate in response to irradiation from the second source of excitation radiation;
e) comparing the recorded luminescence radiation from step (b) and (d),
wherein the detecting steps are performed through an optical filter transmitting radiation with a wavelength greater than 870 nm; and
the irradiating steps are performed through optical filters transmitting radiation of a wavelength of less than 750 nm;
and wherein the comparing includes the step of calibrating the measured data, noise reduction of measured images and thickness calculation using an algorithm based on the Beer-Lambert law.

15. The method according to claim 14, wherein the thin film of material is a thin film of silicon material which is placed on a crystalline silicon wafer, and detected.

16. The method according to claim 15, wherein the thin film of material is a thin film of amorphous silicon material which is placed on a crystalline silicon wafer, and detected.

17. The method according to claim 15, wherein the thin film of material is a thin film of microcrystalline silicon material which is placed on a crystalline silicon wafer, and detected.

18. The method according to claim 15, wherein the thin film of material is a thin film of polycrystalline silicon material which is placed on a crystalline silicon wafer, and detected.

19. The method according to claim 14, wherein the irradiation from the excitation source is performed by LEDs.

20. The method according to claim 19, wherein the first excitation radiation source emits radiation with a mean wavelength of about 465 nm; and the second excitation radiation source emits radiation with a mean wavelength of about 625 nm.

21. The method according to claim 19, wherein the first excitation radiation source emits an optical radiation using blue LED; and the second excitation radiation source emits an optical radiation using red LED.

22. The method according to claim 14, wherein the detection is performed via a GaAs wafer absorbing excitation scattered radiation and solar-control glass which absorbs the infrared component of blue 465 nm and red 625 nm diodes and detected radiation so as not to detect parasitic signals.

23. The method according to claim 14, wherein the detection is performed via a GaAs wafer absorbing excitation scattered radiation and solar-control glass which absorbs the infrared component of blue 465 nm and red 625 nm diodes or detected radiation so as not to detect parasitic signals.

24. The method according to claim 14, wherein the control unit is displaying the calculated thickness and is communicating to the system depositing the thin film.

25. The method according to claim 14, wherein the intensity of excitation radiation is varying.

26. A method of measuring the thickness of a thin film of material exhibiting at least partial excitation radiation absorbance or at least partial luminescence radiation absorbance, wherein the thin film is located on a substrate having luminescent properties using a device comprising:
a source of monochromatic excitation radiation capable of emitting electromagnetic radiation of at least two different wavelengths in succession;
at least one detector adjustable to detect electromagnetic radiation emitted from the substrate simultaneously, or at least partially simultaneously, with the emission of excitation radiation;
wherein
the detector is fitted with a filter transmitting electromagnetic radiation at wavelengths exceeding 870 nm; and
the excitation radiation sources are provided with filters transmitting radiation at wavelengths of less than 750 nm; and wherein the device further comprises a computing unit storing data on the electromagnetic radiation intensities from the substrate and processing the data so as to be adapted to determine the thickness of the thin film on the basis of the Beer-Lambert law.

27. The method according to claim 26, wherein the first source of excitation radiation is at least two LEDs emitting radiation with a mean wavelength of about 465 nm; and the second source of excitation radiation emits radiation with a mean wavelength of about 625 nm.

28. The method according to claim 26, wherein the device comprises of an excitation radiation intensity modulator.

29. The method according to claim 26, wherein the device comprises of a control unit communicating with the deposition system applying the individual films in such a way that the control unit is able to affect the deposition conditions according to the desired thickness of the thin film.

30. A method for detecting the thickness of thin films of solar cells comprising the method according to claim 26, wherein the thin film is a thin film of amorphous hydrogen-doped silicon placed on a crystalline silicon wafer.

31. A method according to claim 30, wherein the device further comprises of a sliding band on which crystalline silicon wafers with deposited thin films move.
